(19) United States
(12) Patent Application Publication
(10) Pub. No.: US 2008/0210846 A1
(43) Pub. Date: Sep. 4, 2008

(54) DRIVEN LIGHT SHIELD FOR IMAGERS

(76) Inventors: James Tynan Andrews, Hopewell, NJ (US); Angela Michelle Ross, Princeton, NJ (US); Peter Alan Levine, West Windsor, NJ (US)

Correspondence Address: PATENT DOCKET ADMINISTRATOR;LOWENSTEIN SANDLER P.C., 65 LIVINGSTON AVENUE, ROSELAND, NJ, 07068, US

(21) Appl. No.: 12/019,091

(22) Filed: Jan. 24, 2008

Related U.S. Application Data
(60) Provisional application No. 60/887,905, filed on Feb. 2, 2007.

(51) Int. Cl. H01L 27/146; H01L 31/18

(52) U.S. Cl. 250/201.1; 438/59; 257/E27.133

(57) ABSTRACT

An actively driven, metal light shield for shielding floating diffusion regions and amplifiers of multi-port CCD or CMOS imager arrays from unwanted light is disclosed. The driven shield overlies one or more floating diffusion regions and buffer amplifiers lying outside the active pixel area of the imager (non-imaging area), which is also protected from unwanted light by a fixed potential shield. The driven shield is directly electrically connected to a source node of a source-follower amplifier stage, i.e., the buffer amplifiers non-inverting output. The fixed potential shield is electrically connected to a DC voltage capable of eliminating charging of the fixed potential shield and substantially overlies the non-imaging area and at least partially overlapping the driven shield. The voltage on the source-follower output follows the voltage impressed on the floating diffusion region capacitance which then drives the driven shield, thereby reducing parasitic capacitance added by the fixed potential shield to floating diffusion regions by about an order of magnitude, which improves the ratio of output voltage of the floating diffusion regions to applied charge. Separate driven shields can also be applied to subsequent stages of source follower amplifiers to reduce parasitic capacitance induced by the fixed potential shield.

### CROSS-REFERENCE TO RELATED APPLICATIONS

This application claims the benefit of U.S. provisional patent application No. 60/887,905 filed Feb. 2, 2007, the disclosure of which is incorporated herein by reference in its entirety.

### FIELD OF THE INVENTION

The present invention relates generally to imagers, and more particularly to an apparatus for shielding floating diffusion regions of a CCD or CMOS imager array.

### BACKGROUND OF THE INVENTION

There are a myriad of designs for top-illuminated CCD imagers. Many designs have an imaging area comprising CCD pixels. The CCD pixels can be arranged, for example, as a two-dimensional array, or for some applications, a one-dimensional linear array. In either case, the charge accumulated in the pixels needs to be converted to an electrical signal that can be amplified or otherwise processed electronically. For this purpose, the CCD arrays may contain one or more output ports which are connected to floating diffusion regions, which are in turn connected to one or more output amplifiers. Each of the floating diffusion regions converts charge to voltage, much like a capacitor. Just like a capacitor, the charge accumulated in a floating diffusion region is related to the resulting output voltage by the equation V=Q/C, expressed as an output responsivity to signal charge measured in microvolts per electron (uV/e). High uV/e is desirable because when a larger signal (in Volts) is generated per electron, noise (referred to electrons) is reduced and imager sensitivity increases.

In a CCD imager, it is desirable to shield all circuitry that is not part of the photosensitive area from light, which create unwanted charge carriers. This includes floating diffusions regions and output amplifiers which, in many designs, lie just outside the CCD pixel areas, which are unshielded. In prior art CCD imagers, the floating diffusion region(s) can be protected by an opaque, metal light shield placed over all areas except the photosensitive CCD pixels. Unfortunately, if this metal shield is not connected to a portion of the CCD imager, then static charge can build up, which can damage the imager through electrostatic discharges.

FIG. 1 shows one method in the prior art for protecting a single floating diffusion region and output amplifiers, while preventing the possibility of build-up of static charge. A floating diffusion region 2 is protected from impinging light 3 by a metal light shield 4 that is grounded. The ground reference is generally the substrate of the CCD imager, which is the same as the ground points of any circuitry on the CCD imager, including floating diffusion regions and output amplifiers. As a result, a parasitic capacitance 6 develops between the floating diffusion region 2 and the metal light shield 4, and additionally, a parasitic capacitance 8 develops between a source node 10 of a first amplifier stage (not shown) and the metal light shield 4.

The effects of this grounding can be better appreciated by reference to FIG. 2, which is a schematic diagram of a single floating diffusion-output amplifier 12 of a top-illuminated CCD imager in the prior art. The floating diffusion region 2 of FIG. 1 is represented electrically as an equivalent capacitance 14, labeled C_{FD}. The floating diffusion capacitance 14 is electrically connected at least to a reset transistor 16, a pulsed current source 18, and the gate 20 of a source follower amplifier 22. The pulse current source 18 represents charge in the CCD imager from the CCD pixels which is converted to a voltage across the floating diffusion capacitance 14. The source follower amplifier 22 is connected to a constant current source load 24 and to a second stage amplifier 26, 28. The second stage amplifier 26, 28 is connected to an output amplifier stage 30, which is in turn connected to an output off-chip load, represented as a resistance R_{load} and capacitance C_{load}. A light shield 32 is represented as covering the floating diffusion capacitance 14, and is directly electrically connected to ground through a link 34, which is part of a metal 1 layer (not shown) that provides the wiring connections of the circuits of the CCD imager. Other metal layers may be used to form the on-chip wiring. The light shield 32 belongs to a metal two layer, which not only covers the floating diffusion capacitance 14, but also the link 34 and the amplifier stages 22-30. Other metal layers may be used to from the light shield.

As can be seen in both FIGS. 1 and 2, the metal 2 light shield 32 causes a number of parasitic capacitances to be created 36, 38, 40, across the floating diffusion capacitance 14, the amplifier stages 22-30, and R_{load} and C_{load}, respectively. The parasitic capacitance 36 adds to the floating diffusion capacitance 14. The increase in capacitance across the floating diffusion due to the light shield 32 results in lower output signal voltage for a given signal charge (uV/e decreases). Devices fabricated with a grounded metal shield have shown a uV/e reduction of 20-25%. The exact value for uV/e reduction is dependent upon device layout and process parameters such as thickness of the insulating layer between the light shield and floating diffusion, wiring to the amplifier gate and the amplifier gate. The parasitic capacitances 38, 40 add additional loads to the amplifier stages 22-30 and across C_{load}, thereby slowing down the response of the amplifier (reducing slew rate).

Another prior method to reduce the effects of unwanted light is to move the amplifiers 22-30 of FIG. 1 far from the imaging area. This can be done by increasing the number of horizontal transfer gates leading to the amplifiers 22-30. This is not always practical, particularly for line array and/or multiport imagers. Still another method can be found in U.S. Pat. No. 6,498,622 to Nakashiba (hereinafter “Nakashiba”). Nakashiba describes the use of driven shields in each pixel of CMOS imagers. Nakashiba defines a unit cell to consist of a photosensitive area, a floating diffusion, a transfer gate to move electrons from the photosensitive region to the floating diffusion, and a source-follower amplifier. Unfortunately, Nakashiba only shields the floating diffusion, not the amplifier stages with a driven shield. Also, the Nakashiba was developed for individual unit cells, which results in an increase in use of real estate not devoted to capturing light in the photosensitive area.

Accordingly, what would be desirable, but has not yet been provided, is a means of shielding floating diffusions and amplifier circuits from unwanted light in an imager without adding significant stray capacitances that reduces uV/e and amplifier performance, and is suitable for an area array, where the driven shields are located outside the unit cell, and shared by multiple unit cells.

### SUMMARY OF THE INVENTION

The above-described problems are addressed and a technical solution is achieved in the art by providing an imager comprising a semiconductor body; an imaging area comprising a plurality of pixels formed on the semiconductor body; a non-imaging area formed external to the imaging area on the semiconductor body; at least one floating diffusion region electrically coupled to at least one of the plurality of pixels and formed on the non-imaging area; at least one buffer amplifier having a non-inverting output electrically coupled to the at least one floating diffusion region and formed on the non-imaging area; and a driven shield substantially overlying the at least one floating diffusion region and electrically connected to the non-inverting output of the at least one buffer amplifier. The imager also includes fixed potential shield electrically connected to a DC voltage capable of eliminating charging of the fixed potential shield and substantially overlying the non-imaging area and at least partially overlapping the driven shield. The fixed potential shield is electrically connected to one of a substrate associated with the semiconductor body, an on-chip DC voltage supply, and through a bond pad to an off chip potential. The fixed potential shield and the driven shield are substantially opaque to light.

The at least one buffer amplifier can comprise at least one source follower amplifier transistor having a gate terminal region and a source terminal region, the floating diffusion region being electrically connected to the gate terminal region via a conductive link, the driven shield being electrically connected to the source terminal region, the driven shield substantially overlying the gate terminal region. The imager can further comprise a second buffer amplifier on the non-imaging area substantially underlying the fixed potential shield and comprising at least one source follower amplifier transistor having a second gate terminal region and a second source terminal region, the second buffer amplifier being electrically coupled to the at least one buffer amplifier; and a second driven shield substantially electrically connected to the second source terminal region, the second driven shield substantially overlying the second gate region, the fixed potential shield at least partially overlapping the second driven shield.

The technique of applying a driven shield can be used to reduce effects of parasitic capacitances induced by a grounded shield on the slew rate of subsequent stages of a buffer amplifier by connecting a second driven shield to a source terminal of a subsequent source follower amplifier. The driven shield can either at least partially underlie the grounded shield or overlie it. The conductive link can be made either of polysilicon or metal. If the conductive link is made of polysilicon, then the driven shield can also overlie the conductive link. The imager can be produced either using a CCD process or a CMOS process.

### BRIEF DESCRIPTION OF THE DRAWINGS

The present invention will be more readily understood from the detailed description of an exemplary embodiment presented below considered in conjunction with the attached drawings, of which:

FIG. 1 is a side view of a grounded shielding technique for a multi-port CCD imager in the prior art;

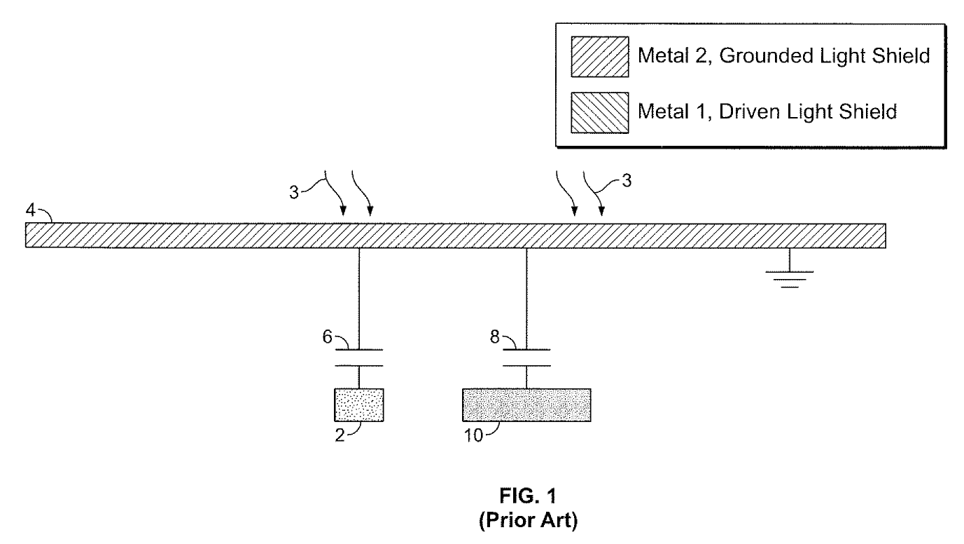

FIG. 2 is an electrical schematic diagram multi-port CCD imager of FIG. 1, showing floating diffusion region and gain stage parasitic capacitances;

FIG. 3 is a top plan view of a simplified diagram of a multi-port CCD or CMOS imager of the present invention with driven shields;

FIG. 4 is a side view of the multi-port imager of FIG. 3;

FIG. 5 is an electrical schematic diagram multi-port imager of FIG. 3, showing floating diffusion parasitic capacitances;

FIG. 6 is a device layout of the imager of FIG. 3, emphasizing the driven shield positions;

FIG. 7 is a device layout of the imager of FIG. 3, emphasizing the fixed potential shield positions relative to the driven shield positions;

FIG. 8 is an amplifier output voltage diagram for the circuits of FIGS. 2, 5, and a similar amplifier circuit with no shielding; and

FIG. 9 is a plot of amplifier bandwidth for the circuits of FIGS. 2, 5, and a similar amplifier circuit with no shielding.

It is to be understood that the attached drawings are for purposes of illustrating the concepts of the invention and may not be to scale.

### DETAILED DESCRIPTION OF THE INVENTION

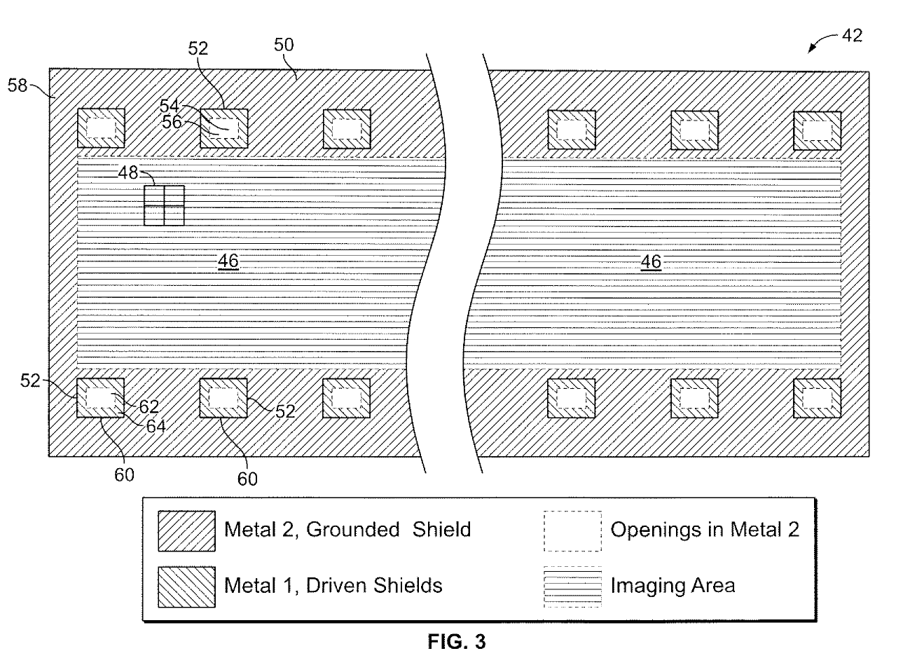

FIG. 3 is a top plan view of a simplified diagram of a multi-port (CCD or CMOS) imager of the present invention with driven shields at each floating diffusion region/amplifier. The multi-port imager 42 includes an inner photosensitive imaging area 46 comprising one or more unit cells 48 containing pixels formed on a semiconductor body (not shown). A non-imaging area 50 lies external to the inner photosensitive imaging area 46 on the semiconductor body. One or more output ports comprising areas 52 are located in the non-imaging area 50. The areas 52 can each contain a portion of an amplifier 54 and/or a floating diffusion region 56. Several unit cells 48 in the inner photosensitive imaging area 46 can be associated with an output port. A fixed potential shield 58 overlies a majority of the non-imaging area 50 and at least partially overlaps each of driven shields 60, the driven shields 60 being depicted as a lighter shaded solid 62 and cross-hatched rectangle 64, while the fixed potential shield 58 extends into the same cross-hatched rectangles 64. The area of the cross-hatched rectangles 64 is preferable small, so that there a small overlap between the fixed potential shield 58 and the driven shields 60 to minimize slew rate loading of amplifier gates. There needs to be at least a small overlap, otherwise, some portions of the floating diffusion regions 56 and the amplifiers 54 would be exposed to unwanted light. In other embodiments, the fixed potential shield 58 can completely overly or underlay the driven shields 60. The fixed potential shield 58 is preferably made of metal, and can be connected to the substrate (ground, not shown) of the multi-port imager 42 or other DC voltage supply such as VDD. The fixed potential shield may also be connected through a bond pad to an off chip ground. In general, the fixed potential shield 58 need only be electrically connected to a DC voltage capable of eliminating charging of the fixed potential shield 58. Driven shields 60, made of an electrically conductive material, preferably metal, overlay each of the areas 52, thus overlaying each of the amplifiers 54 and the floating diffusion regions 56. Both the fixed potential shield 58 and the driven shields 60 are substantially opaque to light.

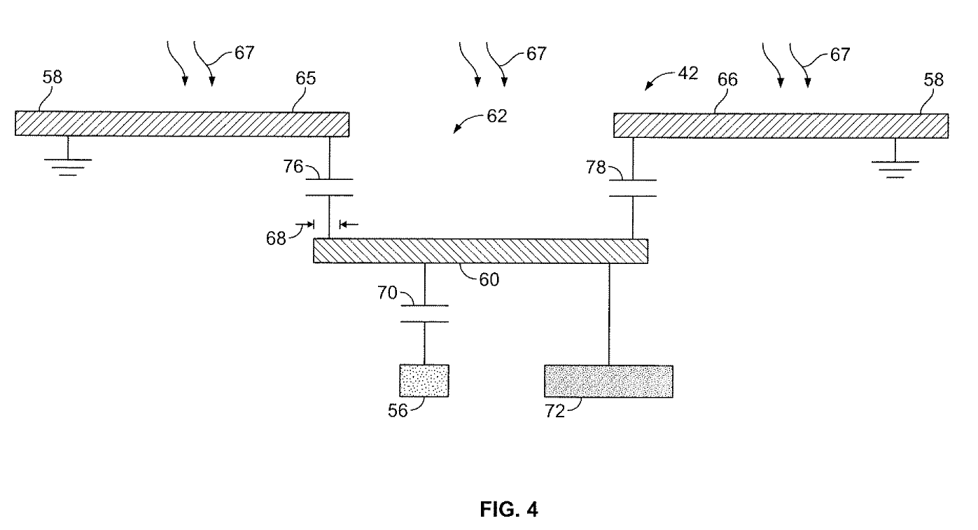

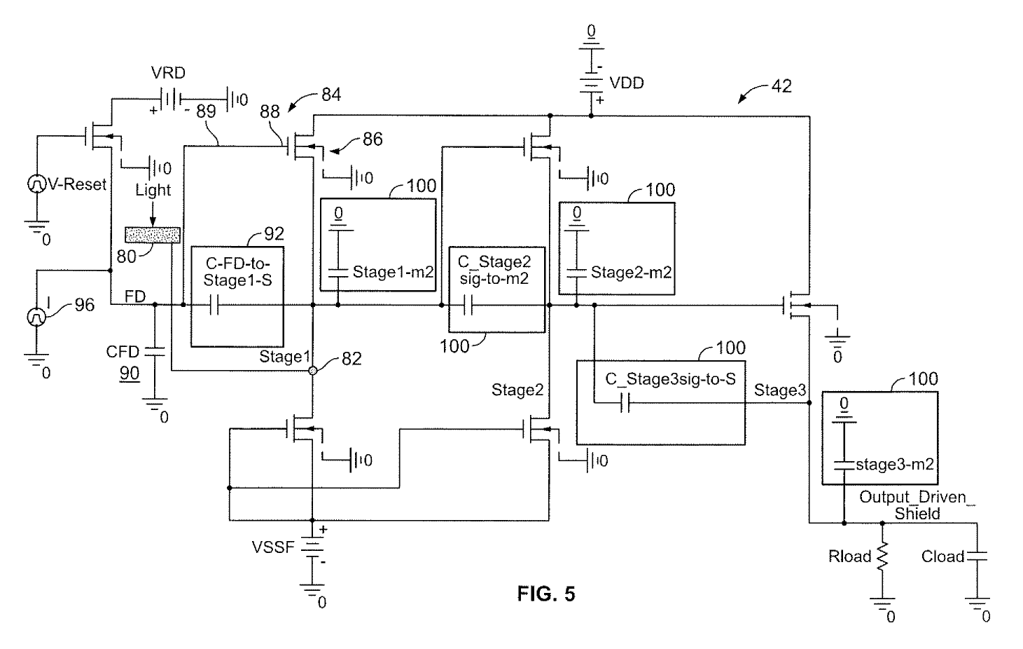

Referring now to FIG. 4, a side view of the multi-port imager 42 is depicted. In a preferred embodiment, the driven shield 60 is shown underlying an opening 62 between two portions 65, 66 of the fixed potential shield 58, all of which may exposed to light 67. However, the driven shield 60 can either underlay or overly the fixed potential shield 58. The shields 58, 60 at least partially overlap in the region 68. A capacitance 70 develops between the floating diffusion region 56 and the driven shield 60. Note that the driven shield 60 is directly electrically connected to a contact 72 of the source node of a source-follower amplifier stage (not shown). Capacitances 76, 78 also develop between the driven shield 60 and the two portions 65, 66 of the fixed potential shield 58. The capacitances 76, 78 between the driven shield 60 and the two portions 65, 66 of the fixed potential shield do not contribute to the uV/e factor of the multi-port imager 42. The value of the capacitance of the capacitor 70 between the floating diffusion region 56 and the driven shield 60 will be discussed below in connection with FIG. 5.

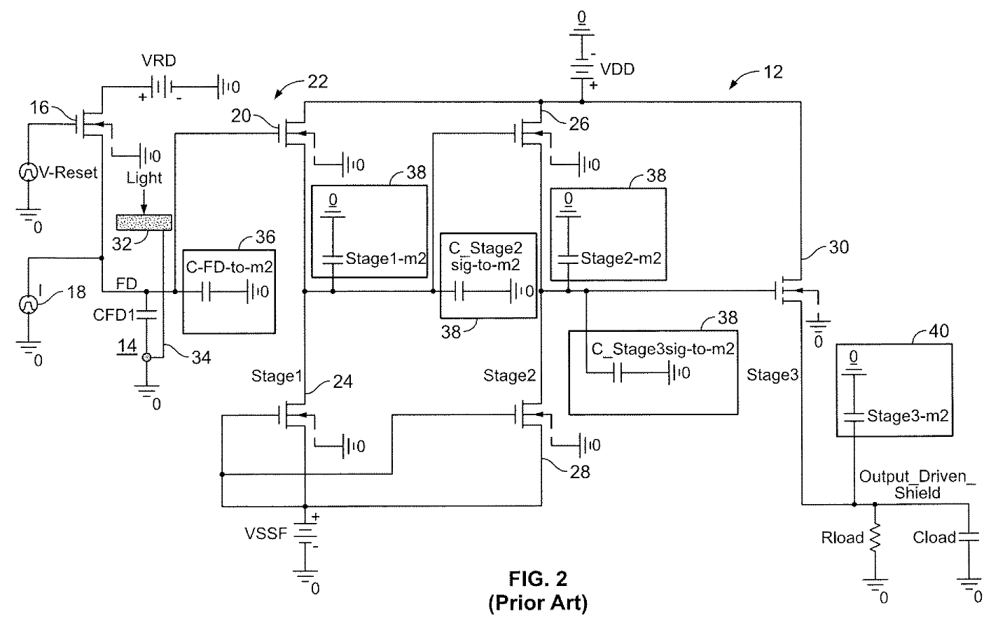

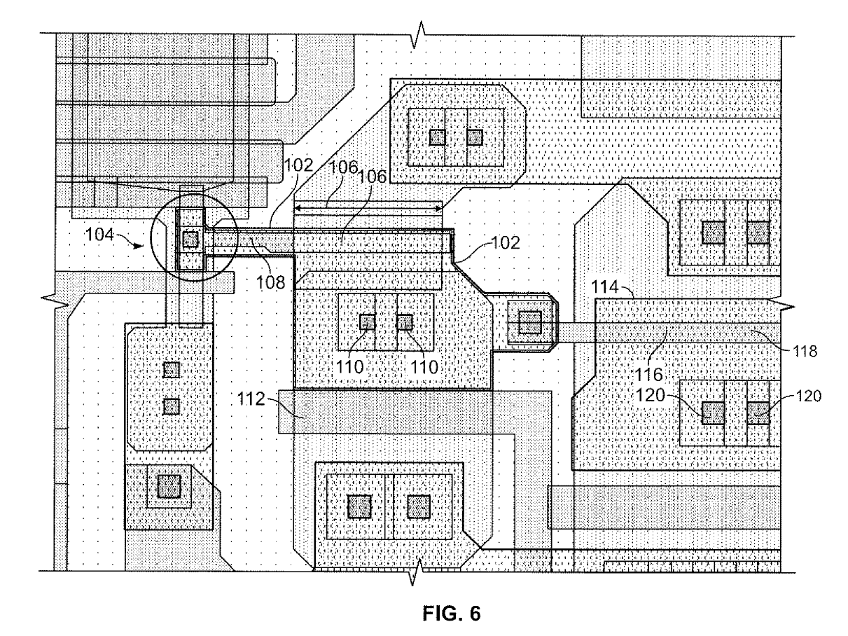

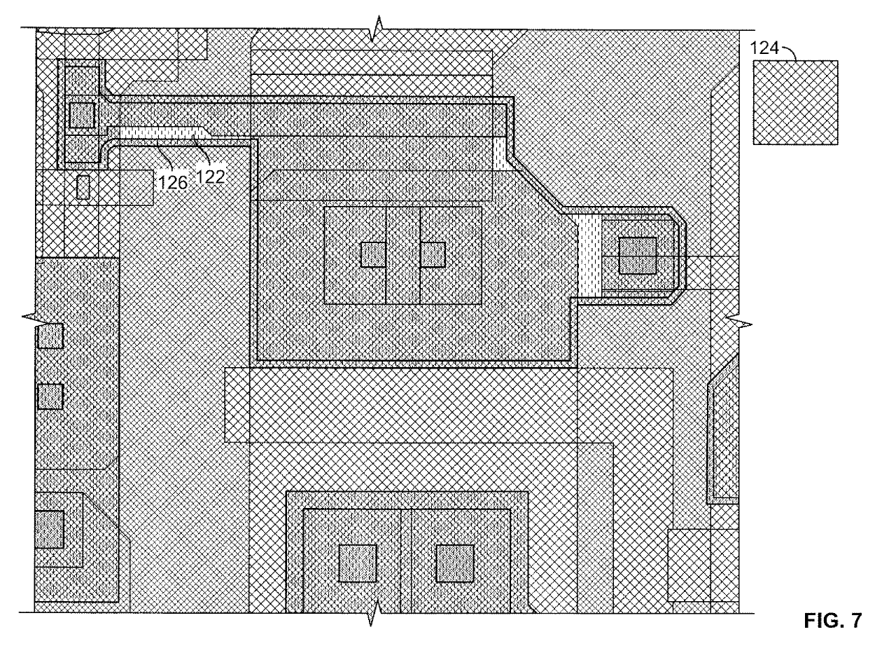

FIG. 5 depicts the electrical schematic diagram of the imager 42 of FIGS. 3 and 4, and is similar to the one described in FIG. 2, except for use of a driven shield 80 and the placement and values for parasitic capacitors. In FIG. 5, a source node 82 of the first stage 84 of a source follower amplifier 86 is connected to the driven shield 80. The driven shield 80 is also connected to a gate 88 of the first stage of the source follower amplifier 86 by a link 89 (to be discussed hereinbelow in connection with FIGS. 6 and 7). The link 89 is made of a conductive material, such as polysilicon or metal. If the link 89 is made of polysilicon, then the driven shield 80 can also overlie the link 89. The capacitor C_{FD} 90 to ground and the capacitance 92 between the gate 88 and to the source node 82 of the first stage source follower amplifier 86, and any stray capacitance between the link 89 and ground contribute to the overall uV/e of the floating diffusion capacitance, which converts charges to a voltage based on pulsed current source 96 representing the accumulated charge on a plurality of CCD unit cells. The current source 96 is pulse on to represent transfer of charge to the floating diffusion 90. The metal plate of the driven shield 80 has a voltage on it, established by the first stage source follower 84 gain that is about 80 to 90 percent of the voltage impressed on the gate 88 (thus defining what is meant by a driven shield). The first stage source voltage follows the floating diffusion region voltage across the floating diffusion capacitor C_{FD} 90. Because the first stage source voltage and the floating diffusion region voltage follow each other, the equivalent capacitance of the first stage source node 98 to ground is reduced by a factor of (1-gain), where gain is typically about 0.9. Reducing the floating diffusion capacitance 90 minimizes the effect of the driven shield 80 and ground shield (not shown) on uV/e by about an order of magnitude. The present invention is not limited to driven shields being connected to source follower amplifiers. In the more general embodiment of the present invention, the driven shield 80 can be directly connected to a non-inverting output node of a buffer.

Although not shown, in other preferred embodiments, a driven shield 80 may overlay the gates that are driven by source nodes for all the amplifier stages and underlay the ground shield (not shown). While these other driven shields have no effect on uV/e, they do reduce the parasitic capacitance values of the amplifier stage parasitics 100, and thus improves slew rate over the amplifier configuration of FIG. 2.

FIG. 6 shows a device layout of the preferred embodiment of the present invention. A first driven shield 102 covers floating diffusion region 104, the gate of a stage-1 amplifier 106, and a polysilicon link 108 extending from the gate of a stage-1 amplifier 106 to driven shield contacts 110 located near the gate of the Stage-1 amplifier load current source 112. A second driven shield 114 is shown covering the gate of a stage-2 amplifier 116. A polysilicon gate 118 is also shown covered by the second driven shield 114 which is connected to stage-2 amplifier 116 by contacts 120. FIG. 7 shows a device layout which includes a ground shield 122 having a ground shield pattern 124 overlying a driven shield 126, which in turn overlies a floating diffusion, link, and stage-1 gate of a source follower amplifier.

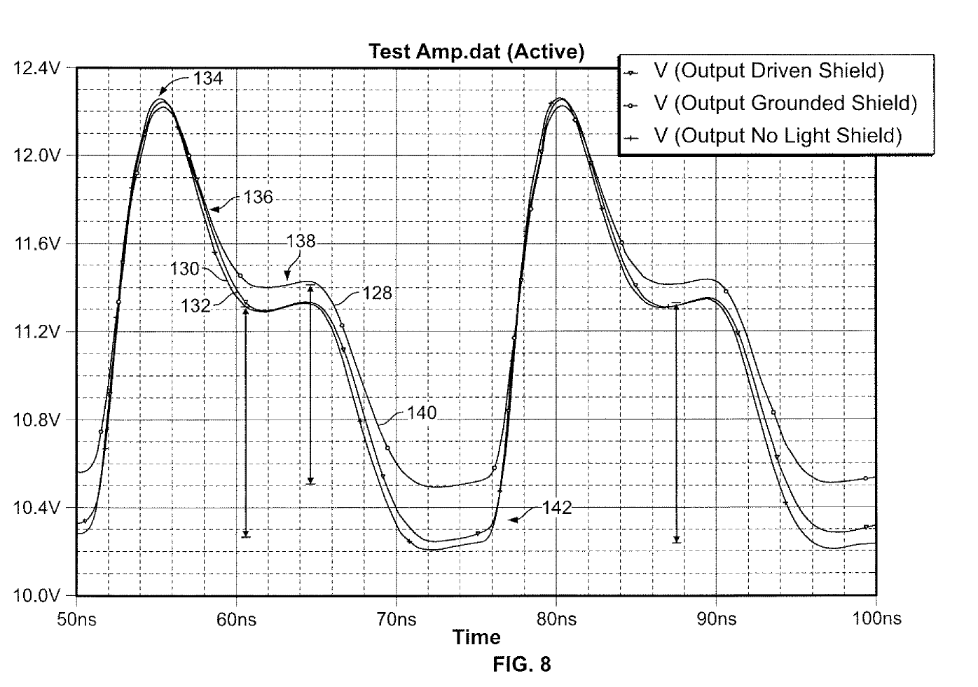

FIG. 8 compares amplifier output signals for the CCD arrays of FIG. 2 (128), FIG. 5 (130), and an output amplifier with no shielding 132, respectively. The initial rise and fall of the waveforms represents floating diffusion reset feedthrough 134 of the floating diffusion, which is then allowed to float on the downward slopes 136 to a discharged state shelf 138. A second downward slop 140 shows the floating diffusion being charged until it reaches a second quiescent shelf 142. Note that the difference between the discharged state and the charged state of the fixed potential shield curve 128 is about 20% smaller than that of the curve with no shielding 132. The difference between discharged state and charged state of the driven shield curve 130, however, has about a 16% higher uV/e at the output than the curve 128 of the fixed potential shield amplifier.

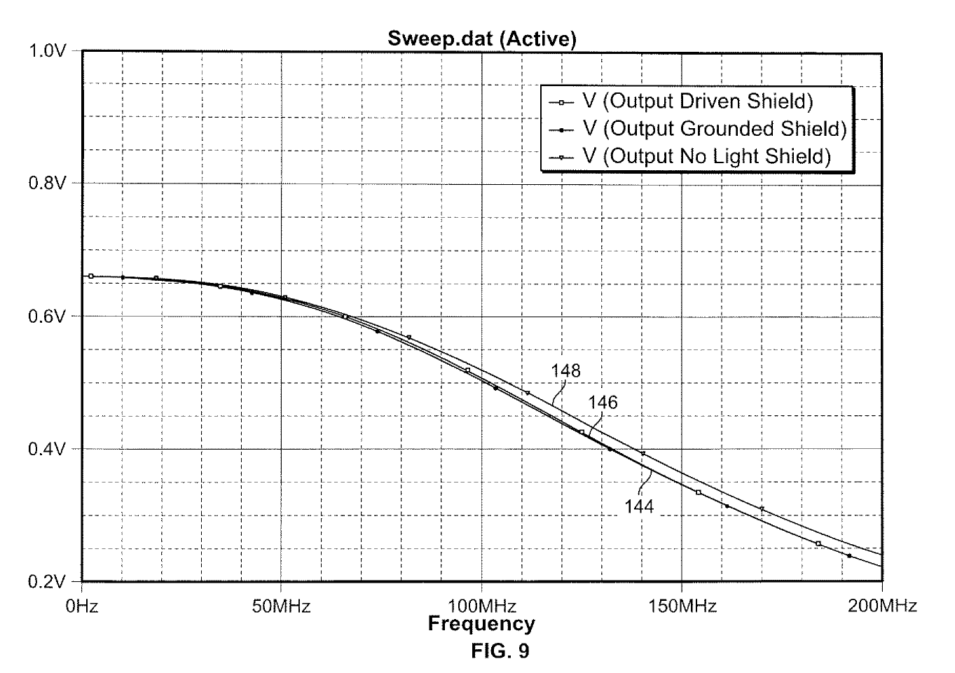

FIG. 9 compares the bandwidth for the amplifiers of the CCD arrays of FIG. 2 (144), FIG. 5 (146), and an output amplifier with no shielding 148, respectively, from 0 Hz to 200 MHz. In the driven shield amplifier, driven shields were added to all stages of the amplifier to reduce impact on bandwidth. There was only a slight decrease in bandwidth when a driven shield was added (curve 146) compared to no shielding 148, which is a significant improvement over the fixed potential shield curve 144.

It is to be understood that the exemplary embodiments are merely illustrative of the invention and that many variations of the above-described embodiments may be devised by one skilled in the art without departing from the scope of the invention. It is therefore intended that all such variations be included within the scope of the following claims and their equivalents.

What is claimed:

1. An imager, comprising:
a semiconductor body;
an imaging area comprising a plurality of pixels formed on said semiconductor body;
a non-imaging area formed external to said imaging area on said semiconductor body;
at least one floating diffusion region electrically coupled to at least one of the plurality of pixels and formed on said non-imaging area,
at least one buffer amplifier having a non-inverting output electrically coupled to said at least one floating diffusion region and formed on said non-imaging area; and
a driven shield substantially overlying said at least one floating diffusion region and electrically connected to said non-inverting output of said at least one buffer amplifier.

2. The imager of claim 1, further comprising a fixed potential shield electrically connected to a DC voltage capable of eliminating charging of the fixed potential shield and substantially overlying said non-imaging area and at least partially overlapping said driven shield.

3. The imager of claim 2, wherein said fixed potential shield is electrically connected to one of a substrate associated with said semiconductor body, an on-chip DC voltage supply, and through a bond pad to an off chip potential.

4. The imager of claim 2, wherein the fixed potential shield and the driven shield are substantially opaque to light.

5. The imager of claim 1, wherein said at least one buffer amplifier comprises at least one source follower amplifier transistor having a gate terminal region and a source terminal region, said floating diffusion region being electrically connected to said gate terminal region via a conductive link, said driven shield being electrically connected to said source terminal region, said driven shield substantially overlying said gate terminal region.

6. The imager of claim 5, further comprising:
a second buffer amplifier on said non-imaging area substantially underlying said fixed potential shield and comprising at least one source follower amplifier transistor having a second gate terminal region and a second source terminal region, said second buffer amplifier being electrically coupled to said at least one buffer amplifier; and
a second driven shield substantially electrically connected to said second source terminal region, said second driven shield substantially overlying said second gate region, said fixed potential shield at least partially overlapping said second driven shield.

7. The imager of claim 2, wherein said driven shield at least partially underlies said fixed potential shield.

8. The imager of claim 2, wherein said driven shield at least partially overlies said fixed potential shield.

9. The imager of claim 5, wherein said conductive link is made of polysilicon, said driven shield substantially overlying said conductive link.

10. The imager of claim 5, wherein said conductive link is made of metal.

11. The imager of claim 1, wherein said plurality of pixels are manufactured using a CCD process.

12. The imager of claim 1, wherein said plurality of pixels are manufactured using a CMOS process.

13. The imager of claim 1, wherein portions of said plurality of pixels are connected to a plurality of ports.

14. An imager, comprising:
a semiconductor body;
an imaging area comprising a plurality of pixels formed on said semiconductor body;
a non-imaging area formed external to said imaging area on said semiconductor body;
at least one buffer amplifier having a non-inverting output in electrical communication with at least one of said plurality of pixels; and
a driven shield substantially electrically connected to said non-inverting output of said at least one buffer amplifier, said driven shield at least partially overlying said at least one buffer amplifier.

15. The imager of claim 14, further comprising a fixed potential shield electrically connected to a DC voltage capable of eliminating charging of the fixed potential shield and substantially overlying said non-imaging area and at least partially overlapping said driven shield.

16. The imager of claim 15, wherein said fixed potential shield is electrically connected to one of a substrate associated with said semiconductor body, an on-chip DC voltage supply, and through a bond pad to an off chip potential.

17. The imager of claim 15, wherein the fixed potential shield and the driven shield are substantially opaque to light.

18. The imager of claim 14, wherein said buffer amplifier comprises at least one source follower amplifier transistor having a gate terminal region and a source terminal region, said driven shield being electrically connected to said source terminal region, said driven shield substantially overlying said gate terminal region.

19. The imager of claim 15, wherein said driven shield at least partially underlies said fixed potential shield.

20. The imager of claim 15, wherein said driven shield at least partially overlies said fixed potential shield.

21. The imager of claim 14, wherein said plurality of pixels are manufactured using a CCD process.

22. The imager of claim 14, wherein said plurality of pixels are manufactured using a CMOS process.

23. A method for manufacturing an imager, comprising the steps of:
providing a semiconductor body;
forming an imaging area comprising a plurality of pixels on the semiconductor body, at least a portion of the semiconductor body comprising a non-imaging area;
forming a floating diffusion region on the non-imaging area, the floating diffusion region being electrically coupled to at least one of the plurality of pixels;
forming at least one buffer amplifier having a non-inverting output on the non-imaging area, the at least one buffer amplifier being electrically coupled to the at least one floating diffusion region; and
forming a driven shield substantially overlying the at least one floating diffusion region, the driven shield being electrically to the non-inverting output of the at least one buffer amplifier.

24. The method of claim 23, further comprising the step of forming a fixed potential shield electrically connected to a DC voltage capable of eliminating charging of the fixed potential shield and substantially overlying said non-imaging area and at least partially overlapping said driven shield.
